(19) United States
(12) Patent Application Publication
(10) Pub. No.: US 2020/0203333 A1
(43) Pub. Date: Jun. 25, 2020

(54) VERTICAL BIPOLAR TRANSISTOR FOR ESD PROTECTION AND METHOD FOR FABRICATING

(71) Applicant: Texas Instruments Incorporated, Dallas, TX (US)

(72) Inventors: Zaichen Chen, Champaign, IL (US); Akram Ali Salman, Plano, TX (US)

(21) Appl. No.: 16/230,510

(22) Filed: Dec. 21, 2018

(51) Int. Cl. H01L 27/02; H02H 9/04; H01L 29/732; H01L 29/08; H01L 29/10; H01L 29/66; H01L 21/8228; H01L 21/225

(52) U.S. Cl. CPC H01L 27/0262; H02H 9/046; H01L 29/732; H01L 21/225; H01L 29/1004; H01L 29/66333; H01L 21/82285; H01L 29/0821

(57) ABSTRACT

An integrated circuit (IC) includes a semiconductor substrate having a first conductivity type and a transistor formed within the substrate that includes a buried layer having a second conductivity type. A first doped region, located between the buried layer and a surface of the substrate, has the first conductivity type and a second doped region, extending from the substrate surface to the buried layer, has the second conductivity type. A third doped region, located between the buried layer and the surface and between the first doped region and the second doped region, has the second conductivity type and a first dopant concentration. A fourth doped region, located between the third doped region and the substrate surface and between the first doped region and the second doped region, has a second dopant concentration less than the first dopant concentration. A method of fabricating the IC is also shown.

### FIELD OF THE DISCLOSURE

Disclosed embodiments relate generally to the field of transistors for electrostatic discharge (ESD) protection. More particularly, and not by way of any limitation, the present disclosure is directed to a vertical bipolar junction transistor (BJT) and method for fabricating.

### BACKGROUND

Integrated circuits (ICs) can be subjected to electrostatic discharge (ESD) events through contact with a charged body such as a human, causing high voltages at one or more pins, pads or terminals of the IC. ESD events can damage an IC through thermal runaway and resultant junction shorting when the amount of charge exceeds the capability of the electrical conduction path through the IC. ESD protection circuits or cells can be provided in an IC to shunt ESD current between a protected pad and a reference node and the use of vertical NPNs to conduct the current is desirable in order to decrease the size of the ESD circuit. However, vertical NPNs may encounter early failure issues from current that moves laterally through the NPN, rather than in the more desirable vertical direction. The lateral NPN current is undesirable because it causes current crowding, current non-uniformity and early failure.

### SUMMARY

Disclosed embodiments provide a vertical bipolar transistor, also referred to a vertical bipolar junction transistor, which can be utilized in providing ESD protection. The collector region is modified by providing a moderately doped buffer region that is laterally offset from the base but lies in the path of conduction and also by fabricating the main body of the collector region as two separate regions, with a first collector region lying adjacent the surface of the semiconductor substrate and being lightly doped and a second collector region lying under the first collector region and being moderately doped. In one embodiment, the first collector region is implanted through a smaller mask opening than is the second collector region, such that the second collector region extends further from the moderately doped buffer region than does the first collector region and extends under a portion of the base of the NPN transistor. These differences in doping draw the current deeper into the transistor, which provides a more diffuse current density and works to decrease the likelihood of premature catastrophic failures. While such embodiments may be expected to improve reliability of such integrated circuits employing the vertical bipolar transistor for ESD protection, no particular result is a requirement of the described invention(s) unless explicitly recited in a particular claim.

In one aspect, an embodiment of an integrated circuit is disclosed. The integrated circuit includes a semiconductor substrate having a first conductivity type; and a transistor formed within the semiconductor substrate the transistor comprising: a buried layer located within the semiconductor substrate and having a second conductivity type; a first doped region having the first conductivity type located between the buried layer and a surface of the substrate; a second doped region having the second conductivity type extending from the substrate surface to the buried layer; a third doped region, located between the buried layer and the surface and between the first doped region and the second doped region, the third doped region having the second conductivity type and a first dopant concentration; and a fourth doped region located between the third doped region and the substrate surface and between the first doped region and the second doped region, the fourth doped region having a second dopant concentration less than the first dopant concentration.

In another aspect, an embodiment of a transistor is disclosed. The transistor includes a base region at a surface of a semiconductor substrate, the base region being doped P-type; an emitter that is N-type and is formed in the base region; an N-type buffer region extending from the substrate surface into the substrate; and an N-type collector comprising: a first collector region that has a first dopant concentration and that extends from the buffer region towards the base region a first distance; a second collector region that has a second dopant concentration that is higher than the first dopant concentration, underlies the first collector region and extends from the buffer region towards the base region a second distance; and a collector contact region at the surface of the substrate, the collector contact region being doped a third dopant concentration that is higher than the second dopant concentration, is connected to the buffer region, and is separated from the first collector region by a region having a fourth dopant concentration lower than both the first dopant concentration and the third dopant concentration.

In yet another aspect, an embodiment of a method of fabricating an integrated circuit is disclosed. The method includes providing a semiconductor substrate having a first P-type epitaxial layer containing an N type buried layer and a second P-type epitaxial layer overlying the first P-type epitaxial layer; implanting a first N-type dopant into the second epitaxial layer and annealing the semiconductor substrate thereby forming a moderately doped collector region; growing a third P-type epitaxial layer on the second P-type epitaxial layer; implanting a second N-type dopant in the third P-type epitaxial layer and annealing the semiconductor substrate forming a lightly doped collector region overlying the moderately doped collector region; implanting a third N-type dopant thereby forming a moderately doped buffer region that extends from a surface of the semiconductor substrate to the moderately doped collector region and the N-type buried layer; and implanting a fourth N-type dopant at a surface of the substrate over the lightly doped collector region thereby forming an N++ collector contact region that is connected to the buffer region.

### BRIEF DESCRIPTION OF THE DRAWINGS

Embodiments of the present disclosure are illustrated by way of example, and not by way of limitation, in the figures of the accompanying drawings in which like references indicate similar elements. It should be noted that different references to “an” or “one” embodiment in this disclosure are not necessarily to the same embodiment, and such references may mean at least one. Further, when a particular feature, structure, or characteristic is described in connection with an embodiment, it is submitted that it is within the knowledge of one skilled in the art to effect such feature, structure, or characteristic in connection with other embodiments whether or not explicitly described. As used herein, the term “couple” or “couples” is intended to mean either an indirect or direct electrical connection unless qualified as in “communicably coupled” which may include wireless connections. Thus, if a first device couples to a second device, that connection may be through a direct electrical connection, or through an indirect electrical connection via other devices and connections.

The accompanying drawings are incorporated into and form a part of the specification to illustrate one or more exemplary embodiments of the present disclosure. Various advantages and features of the disclosure will be understood from the following Detailed Description taken in connection with the appended claims and with reference to the attached drawing figures in which:

FIGS. 1A and 1B depict examples of vertical NPN bipolar transistors according to embodiments of the disclosure;

FIG. 2 depicts a current conduction profile for the vertical NPN transistor of FIG. 1A according to an embodiment of the disclosure;

FIG. 3A depicts a simulated transmission line pulse (TLP) current-voltage (I-V) curve for an NPN transistor similar to FIG. 1A but without the disclosed buffer region;

FIG. 3B depicts a simulated TLP I-V curve for the transistor of FIG. 1A with the disclosed buffer region according to an embodiment of the disclosure;

FIG. 4 depicts simulated TLP I-V curves for a vertical NPN transistor both with and without the disclosed buffer and extended base;

FIG. 5 illustrates a high level block diagram of an ESD protected IC into which the disclosed vertical bipolar transistors may be incorporated to protect one or more terminals of the IC according to an embodiment of the disclosure;

FIG. 6 depicts a flowchart of a method of fabricating a vertical bipolar transistor according to an embodiment of the disclosure;

FIGS. 6A-6D depict additional elements that may be part of the method of FIG. 6;

FIGS. 7A-7G depict various points in the fabrication of a vertical bipolar transistor according to an embodiment of the disclosure; and

FIG. 8 depicts an example vertical NPN bipolar transistor according to some baseline implementations.

### DETAILED DESCRIPTION OF THE DRAWINGS

Specific embodiments of the invention will now be described in detail with reference to the accompanying figures. In the following detailed description of embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

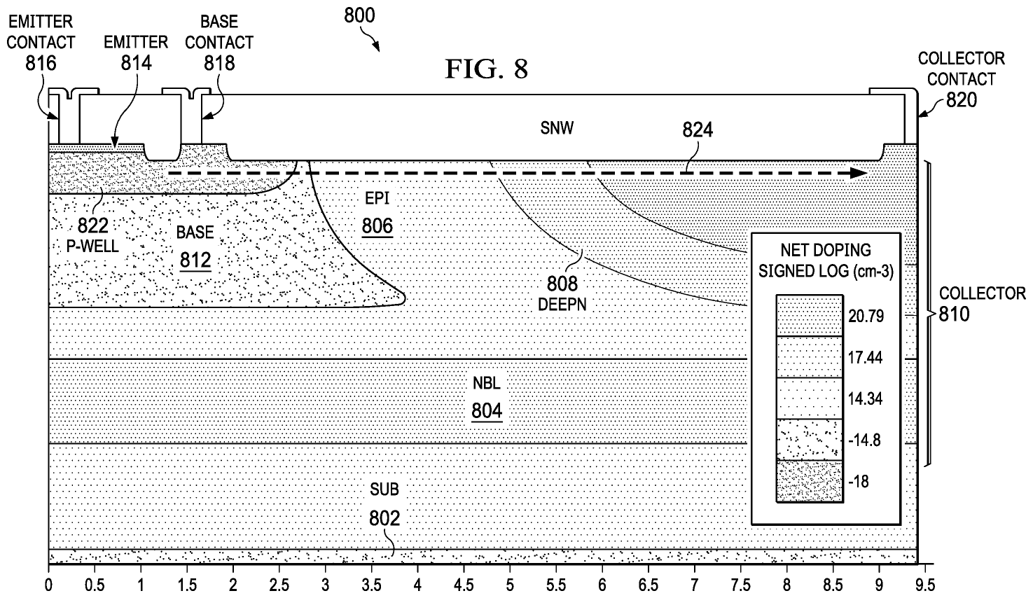

FIG. 8 depicts a cross-section of a vertical NPN 800 and the doping levels associated with vertical NPN 800 according to some baseline implementations. Vertical NPN 800 includes a P-type substrate 802 on which a P− epitaxial (EPI) layer 806 has been grown and utilized to form base region 812. An N-type buried layer (NBL) 804 has been formed within the epitaxial layer 806 and a deep N-well (DEEPN) 808 has been implanted with N-type dopants that are then diffused such that the concentration of dopants is greatest near a collector contact 820 and becomes lightest near the base region 812. A collector 810 includes the NBL 804, DEEPN 808, and collector contact 820. Emitter 814 is formed in P-well 822 and has an emitter contact region 816. Base contact 818 provides a connection to base region 812.

Vertical bipolar junction transistors, such as vertical NPN 800, can have a competing parasitic lateral BJT inherent in their construction that can divert current from the desired vertical direction to a lateral direction just under the surface of the collector, as shown by the arrow 824. This lateral current has been shown to be the source of greatest failure in a BJT utilized for ESD protection. ESD events can cause a current of between 2 amps and 10 amps within a few hundred nanoseconds within an IC chip. If too much of that current is conducted along the lateral conduction path, the charge density associated with the current passing through the base-collector region may exceed the charge density in the depletion region. When this occurs, the depletion region ceases to exist and there is a build-up of majority carriers from the base in the base-collector depletion region. The dipole formed by the positively and negatively charged ionized donors and acceptors is pushed into the collector and replaced by positively charged ionized donors and a negatively charged electron accumulation layer, which is referred to as base push out. This effect, known as the Kirk effect, leads to early failure of the BJT and a failure of ESD protection.

To avoid the Kirk effect and related effects of the lateral component of the BJT transistor, it is desirable to direct the ESD current to the vertical component of the BJT while prohibiting, to the extent possible, the current conduction in the lateral component after the BJT device is triggered. The discussion herein focuses on NPN transistors; however it will be understood that the disclosed improvements can be applied to vertical PNP transistors by reversing the doping of the various regions discussed.

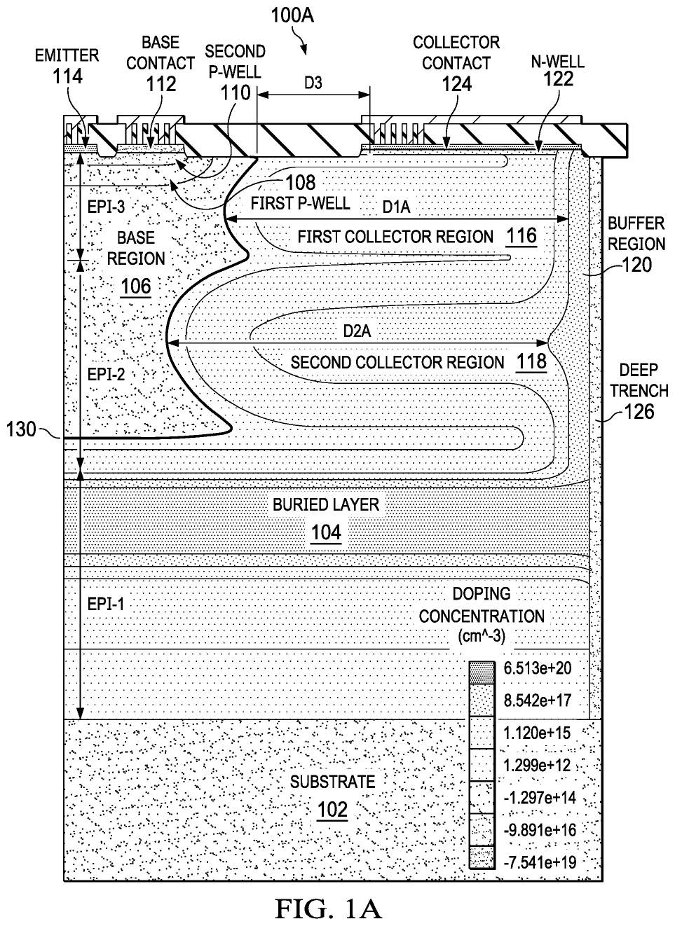

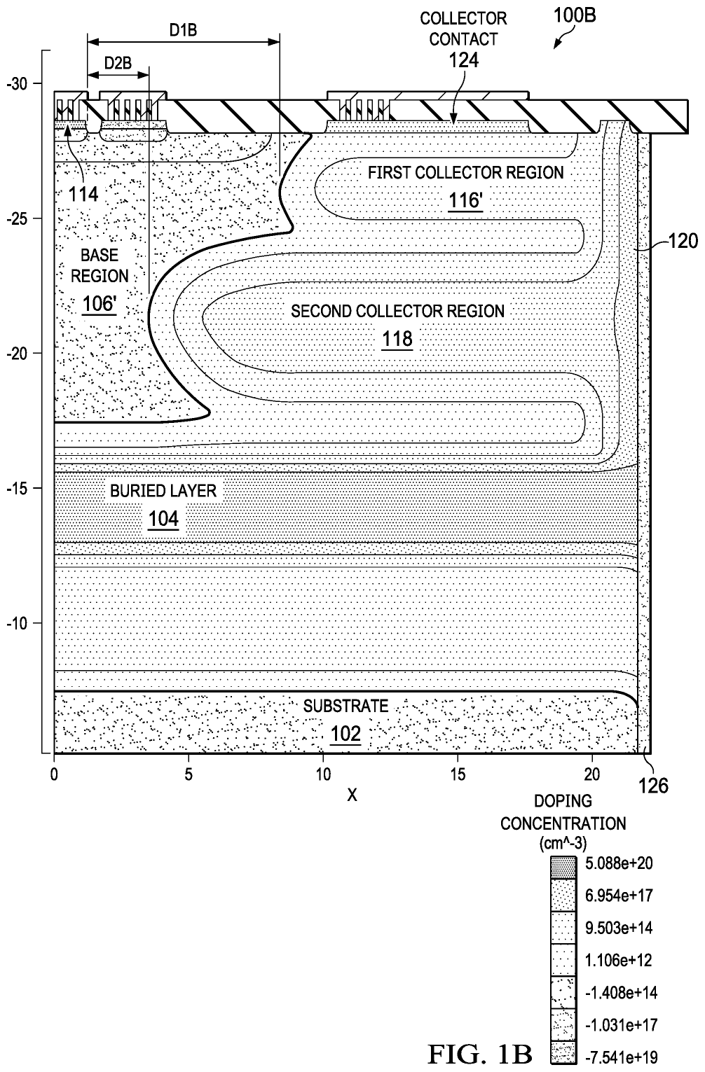

FIG. 1A depicts an example of a vertical bipolar transistor 100A according to an embodiment of the disclosure. Vertical bipolar transistor 100A, which is an NPN transistor, includes a substrate 102 on which three epitaxial layers EPI-1, EPI-2, and EPI-3 have been grown. An N-type buried layer 104 has been formed in epitaxial layer EPI-1 and generally extends across the semiconductor substrate. A base region 106 is formed by portions of P-type epitaxial layers EPI-2 and EPI-3; in at least one embodiment the doping of base region 106 is modified by a P-type buried layer implant (not specifically shown) that is used to contribute to the gain of the vertical bipolar transistor. The P-type base of vertical bipolar transistor 100A also includes a first P-well 108 having a dopant concentration greater than that of the EPI-3 layer, a second P-well 110 having a dopant concentration greater than that of the first P-well 108, and a base contact 112 having a dopant concentration greater than that of the second P-well 110, e.g. P++. N-type emitter 114 is formed at a surface of the silicon of second P-well 110 in base region 106. The N-type collector of vertical bipolar transistor 100A includes a first collector region 116, which is formed at the surface of the third epitaxial layer EPI-3, a second collector region 118, which is formed in the second epitaxial layer EPI-2, a heavily doped N-type buried layer 104, a buffer region 120, an N-well 122 and a collector contact region 124. The various doped regions form a vertical NPN including the emitter 114, the base region 106 and the buried layer 104, and a horizontal NPN including the emitter 114, the base region 106, the first collector region 116 and the second collector region 118.

In one embodiment, substrate 102 is doped P+ and each of the epitaxial layers EPI-1, EPI-2, EPI-3 is doped P−, e.g., with about 1 e15 atoms/cm³ boron. In other embodiments, such as the illustrated embodiments, epitaxial layers EPI-1, EPI-2, EPI-3 can have different doping levels in order to engineer the gain of the vertical transistor versus the lateral transistor. In one such embodiment, N-type buried layer 104 is implanted, e.g., with arsenic, antimony or another suitable N-type dopant, after the first epitaxial layer EPI-1 is grown; N-type buried layer 104 has a maximum concentration of about 5 e18 atoms/cm³. In the embodiment shown, second collector region 118 is implanted after the growth of epitaxial layer EPI-2 and is moderately doped, e.g., with phosphorus to about 8.5 e17 atoms/cm³ at maximum concentration. First collector region 116 is implanted after the growth of epitaxial layer EPI-3 and is lightly doped, e.g., with phosphorus to about 5.5 e16 atoms/cm³ at the maximum concentration, with lighter concentrations of dopant being provided between first collector region 116 and each of base region 106 and collector contact region 124. In the embodiment shown, while both the first collector region 116 and the second collector region 118 are formed by ion implantation using the same mask, second collector region 118 is formed using a high energy ion implantation and is subjected to additional diffusion time such that first collector region 116 extends a first distance D1A from buffer region 120 towards base region 106 and second collector region 118 extends a second distance D2A from buffer region 120, the second distance D2A being slightly larger than first distance D1A. Accordingly, second collector region 118 extends slightly further into base region 106 than does first collector region 116. Together, first collector region 116, second collector region 118 and buried layer 104 form a junction 130 with those portions of the second epitaxial layer EPI-2 and the third epitaxial layer EPI-3 that form the base region 106. The higher maximum doping concentration in second collector region 118 with regard to first collector region 116 is provided to encourage ESD current to flow through second collector region 118 as opposed to first collector region 116 due to a lower resistance.

Some embodiments include a buffer region 120 located between a deep trench contact 126 and the first and second collector regions 116, 118. The buffer region 120 may be formed by a vertical implant that extends from the surface of the semiconductor substrate to the second collector region 118 and the N-type buried layer 104. The buffer region 120 connects to the N-well 122 and provides a path for conduction between the collector contact region 124 and each of the first and second collector regions 116, 118 and buried layer 104. In some embodiments and as illustrated, buffer region 120 is placed adjacent to deep trench contact 126 in order to utilize the fabrication of deep trench contact 126 to provide an opportunity for doping buffer region 120. In some other embodiments, not shown, the buffer region 120 is placed laterally at other locations within the collector that can provide the desired current path. The position of collector contact region 124 from the edge of the lightly doped base region 106 may also be significant, as this position may determine the breakdown of the collector, which in turn determines the voltage rating of a pin with which vertical bipolar transistor 100A can be utilized to provide ESD protection, e.g., 5V, 20V, 40V, etc. In various embodiments the collector contact region 124 is about centered in the middle of first collector region 116. The edge of collector contact region 124 can be distanced away from the edge of first collector region 116 by a distance D3 that is between five to forty-five percent the distance D1A that the first collector region 116 extends away from the buffer region 120.

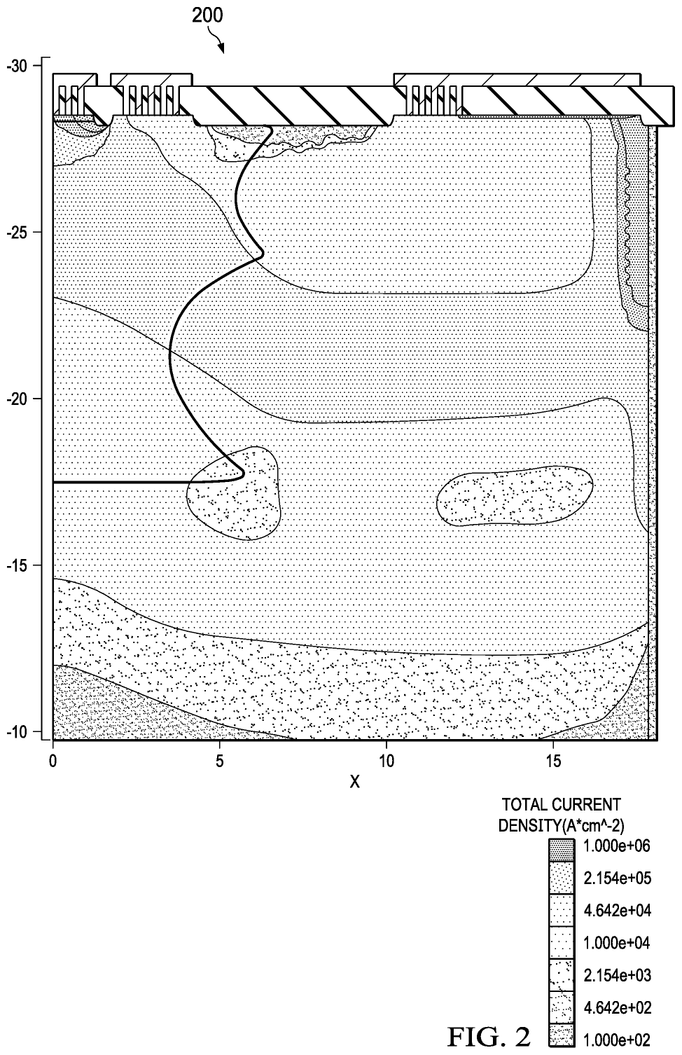

FIG. 2 illustrates a simulated current conduction profile 200 for vertical bipolar transistor 100A, with only the junction 130 shown for orientation between base region 106 and the combined collector region (first collector region 116, second collector region 118 and buried layer 104). As current conduction profile 200 illustrates, the heaviest current occurs through second collector region 118, with lighter currents moving through first collector region 116 and N-type buried layer 104. By pulling the current deeper into the collector region, a broader conduction path is achieved; the maximal current handling capability (It2) of the NPN bipolar transistor is thereby increased by more than three times according to a TCAD prediction. Additionally, the process of fabricating vertical bipolar transistor 100A is compatible with any combined bipolar/complementary metal oxide semiconductor (BiCMOS) technology.

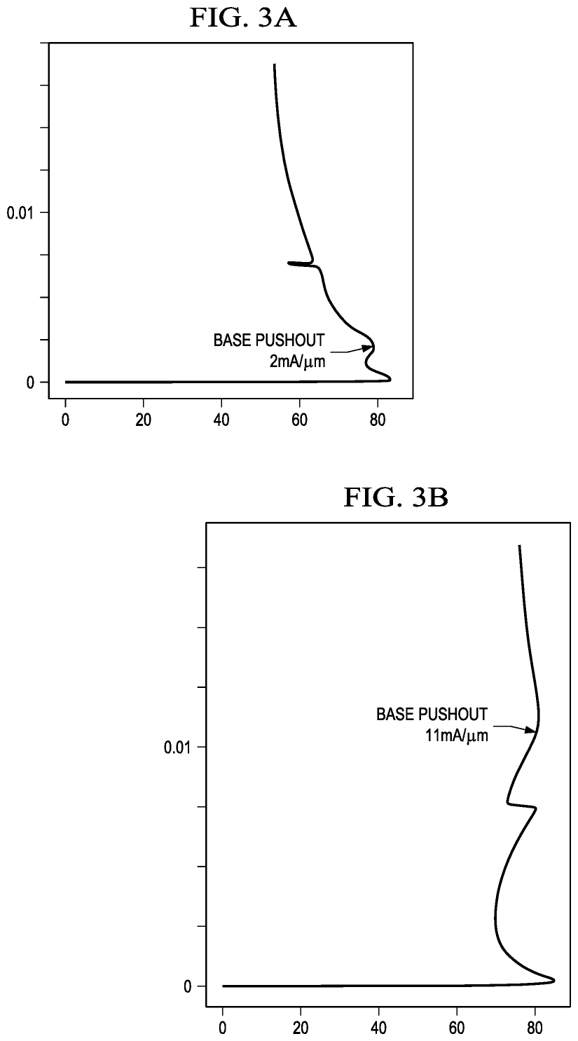

FIG. 3A depicts a simulated transmission line pulse (TLP) I-V curve for an NPN bipolar transistor similar to vertical bipolar transistor 100A, but without the moderately doped buffer region 120. An arrow directs attention to the point at which base pushout began in this transistor, at only 2 mA/μm, with the negative current trend thereafter indicating a failing transistor. FIG. 3B provides a simulated TLP I-V curve for the vertical bipolar transistor 100A, for the case in which the transistor 100A includes the described buffer region 120. In this figure, base pushout begins about 11 mA/μm; this value is more than a five-fold increase in the current threshold at which the Kirk effect starts.

FIG. 1B depicts a vertical bipolar transistor 100B that includes the disclosed buffer region 120 of vertical bipolar transistor 100A and also includes a modified first collector region 116′, which in turn affects the shape of base region 106′. The modifications for vertical bipolar transistor 100B decrease the width of first collector region 116′, which laterally extends the portion of base region 106′ that is near the surface of the semiconductor substrate so that a greater portion of base region 106′ overlies second collector region 118. This modification is expected to hinder the lateral NPN current path and direct the current to the vertical path after the device triggers laterally. Other regions in vertical bipolar transistor 100B may be essentially the same as the vertical bipolar transistor 100A (FIG. 1A), as indicated by their same numbering. In FIG. 1A, both first collector region 116 and second collector region 118 can be implanted using a single mask. In the embodiment of FIG. 1B, second collector region 118 can be fabricated using the same mask as previously, while first collector region 116′ may be fabricated using a second mask that includes a smaller exposed area through which first collector region 116′ is implanted, such that first collector region 116′ is recessed from the base region 106′ relative to the second collector region 118. The exposed area through which first collector region 116′ is implanted may be sized such that in the completed vertical bipolar transistor, a first lateral distance D1B (e.g. in a direction parallel to the substrate 102 surface) between emitter 114 and first collector region 116′ is greater than a second lateral distance D2B between emitter 114 and second collector region 118. In embodiments utilizing the laterally extended base region, the ratio of D1B:D2B is between about 2.1 and about 4.5 inclusive, while the same ratio in embodiments that do not laterally extend the base region is between about 1 and about 2.

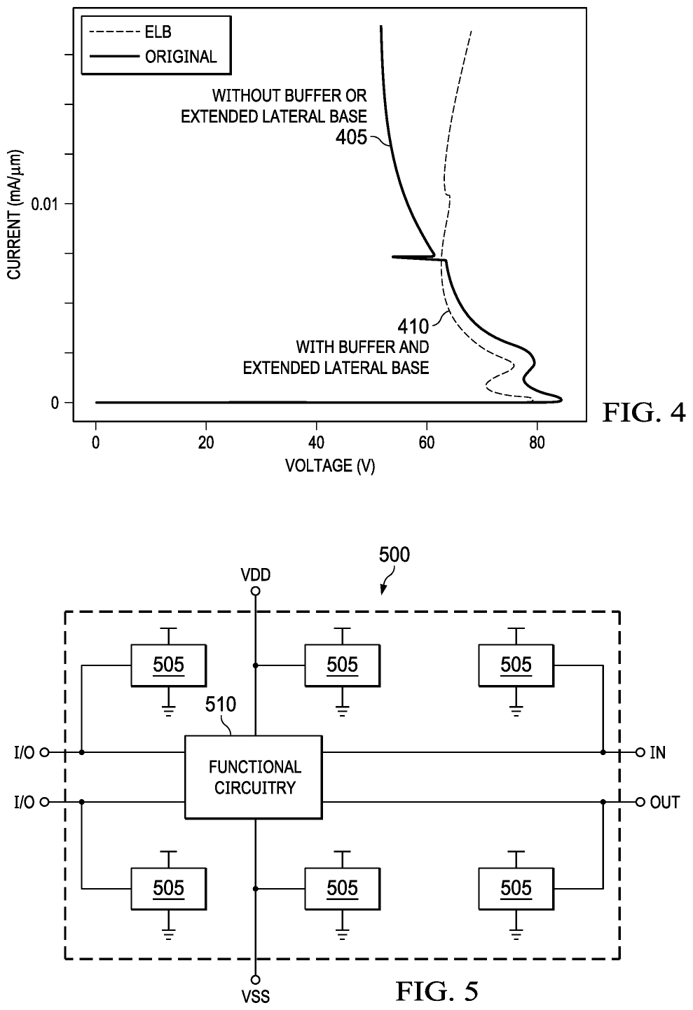

FIG. 4 depicts two superimposed simulated I-V curves. A first curve 405 is a reproduction of the curve of FIG. 3A in which no buffer or extended lateral base is present, e.g. representative of conventional implementations. As noted before, this curve exhibits base pushout and failure beginning at a current density of about 2 mA/μm. A second curve 410 is for the vertical bipolar transistor 100B which has both the disclosed buffer region 120 and the disclosed extended lateral base region 106′. The curve 410 shows that the transistor 100B can be expected to provide an improvement in failure current by more than two times (100% increase). This improvement increases design flexibility, because lateral conduction-induced failure may be significantly reduced while the process remains compatible with BiCMOS techniques.

FIG. 5 illustrates a high level block diagram of an IC 500 into which one or both of vertical bipolar transistors 100A, 100B functioning as ESD protection devices 505 may be incorporated to protect one or more pins, pads or terminals of IC 500. IC 500 includes functional circuitry 510, which may be integrated circuitry that realizes and carries out a desired functionality of IC 500, such as that of a digital IC (e.g., digital signal processor) and/or analog IC (e.g., amplifier or power converter). The capability of functional circuitry 510 provided by IC 500 may vary, for example ranging from a simple device to a complex device. The specific functionality contained within functional circuitry 510 is not limited to any particular functionality in the disclosed embodiments.

IC 500 also includes a number of external terminals by way of which functional circuitry 510 carries out its function. A few of those external terminals are illustrated in FIG. 5, although it will be understood that the number of terminals and their function can vary widely. In the example of IC 500, two terminals operate as common input and output terminals (I/O), by way of which functional circuitry 510 can receive incoming signals and can generate outputs, as well known in the art. A representative input terminal IN is also shown for IC 500, as is a representative output terminal OUT. Each of terminals IN, OUT is also connected to functional circuitry 510. Power supply terminal VDD receives a positive power supply voltage in this example, while ground terminal VSS is provided to receive a reference voltage, such as system ground. Although not shown, the ground shown connected to the ESD protection devices 505 is coupled to VSS, such as resistively coupled or directly connected.

Each ESD protection device 505 includes a vertical bipolar transistor consistent with the disclosure as exemplified by the vertical bipolar transistors 100A and 1008. The ESD protection device is coupled between an input provided by a suitable trigger circuit (not specifically shown) and a ground reference. IC 500 includes an instance of an ESD protection device 505 connected to each of its terminals. Each ESD protection device 505 is connected to its corresponding terminal in parallel with the functional circuitry 510. ESD protection devices 505 are also connected to power supply and reference voltage terminals VDD, VSS, in parallel with functional circuitry 510. However, in some applications, some terminals of the device being protected may be self-protecting, such as power supply terminals protected by a diode. Terminals also can be protected against different levels of ESD strike (Human Body Model (HBM), Charged Device Model (CDM), IEC, etc.).

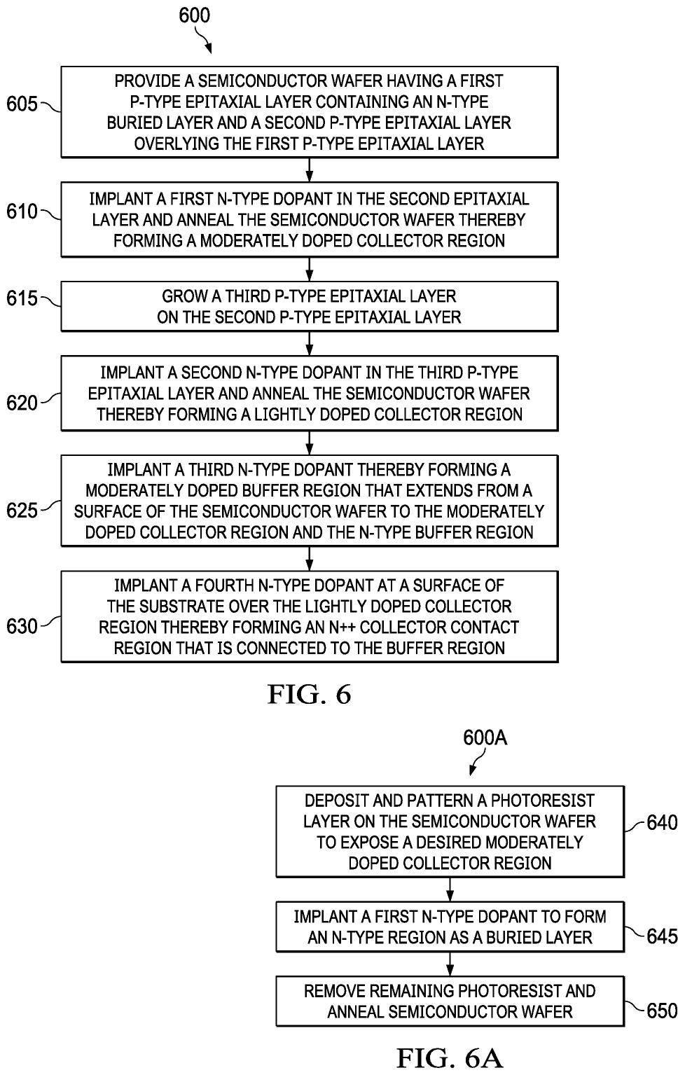

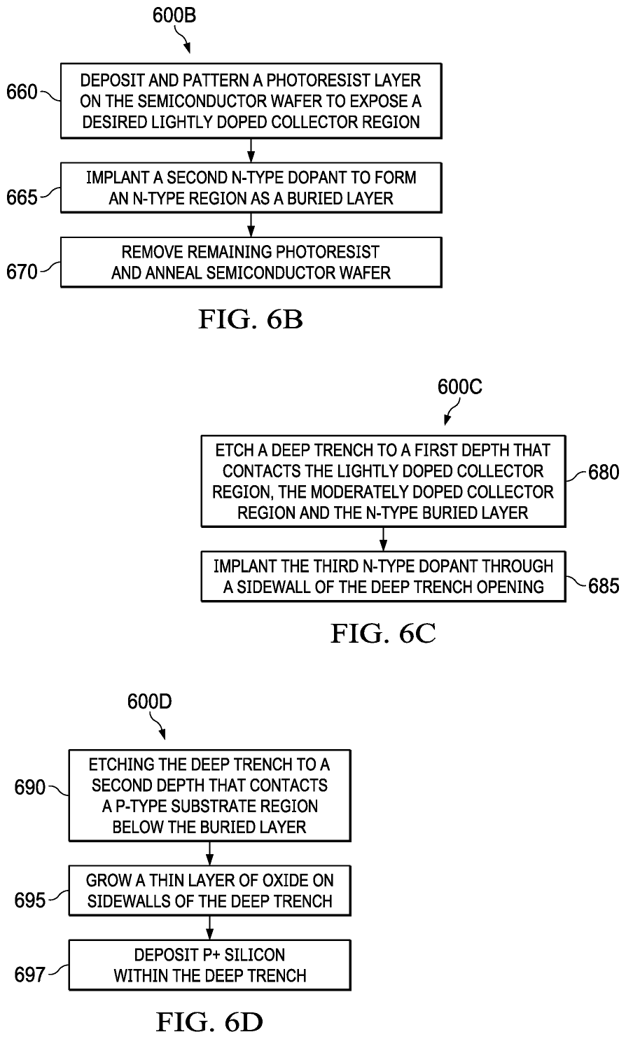

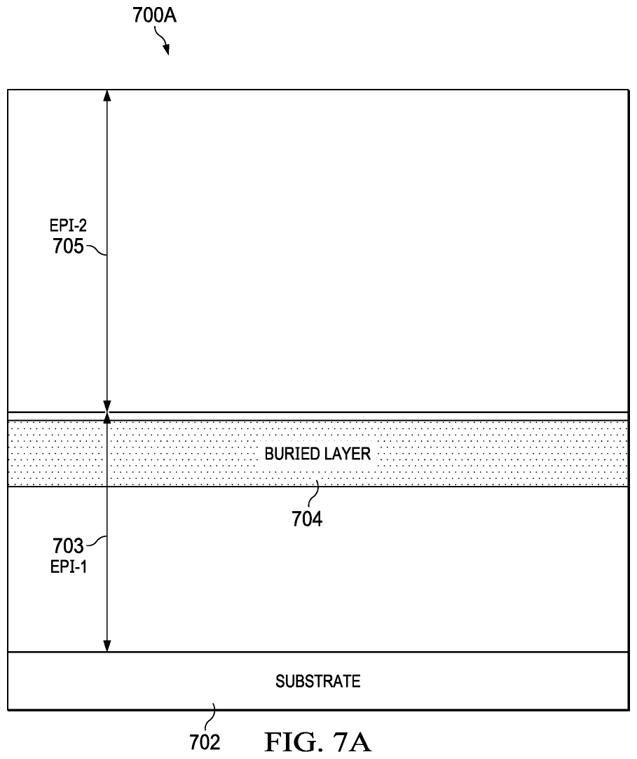

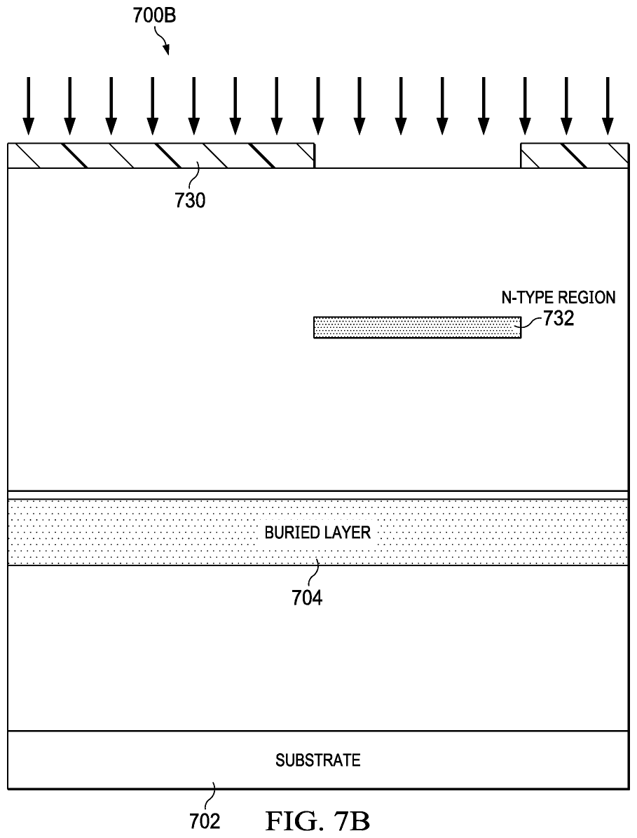

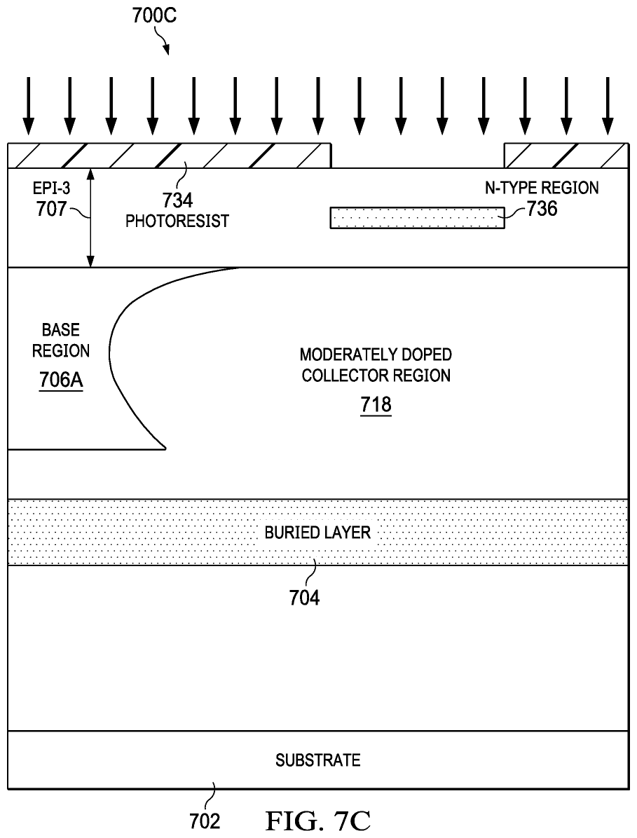

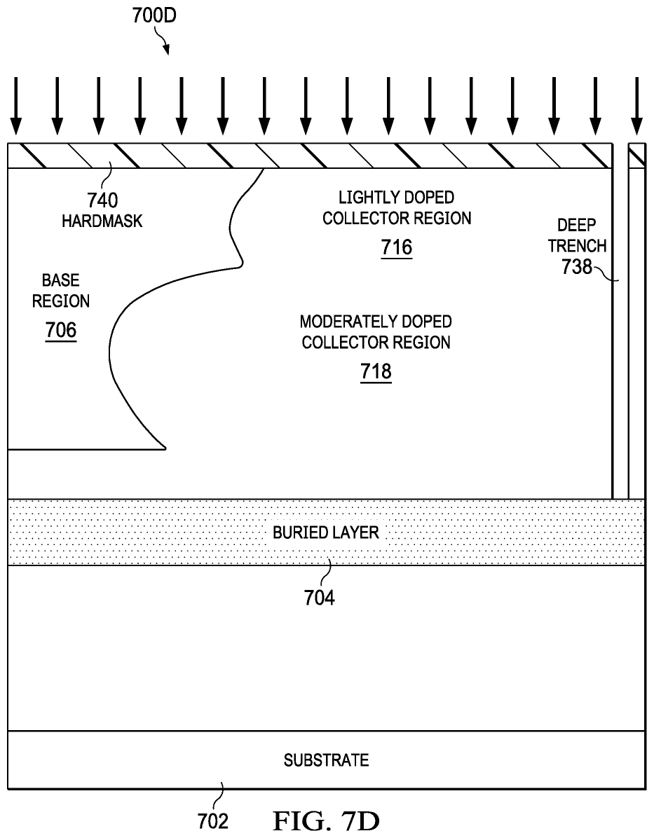

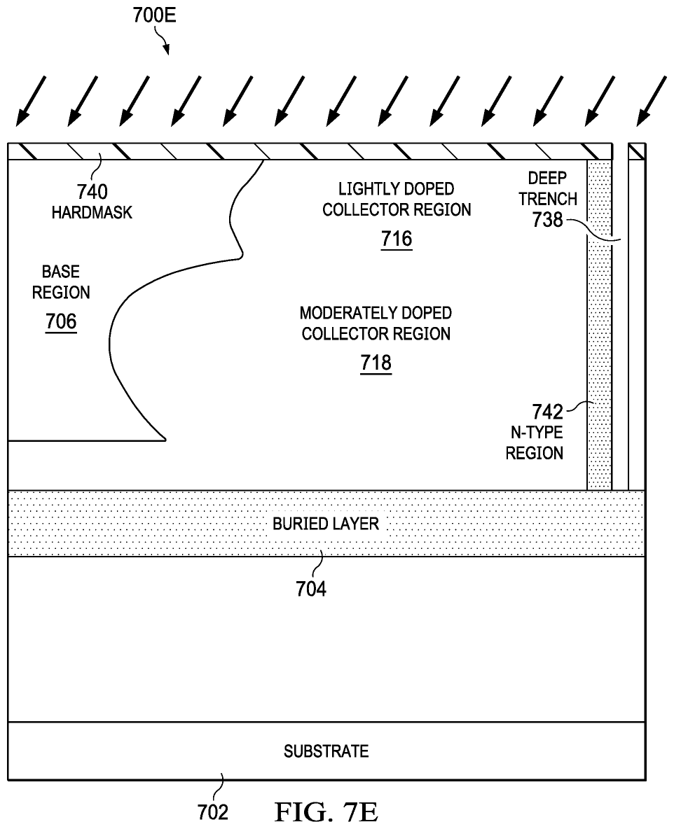

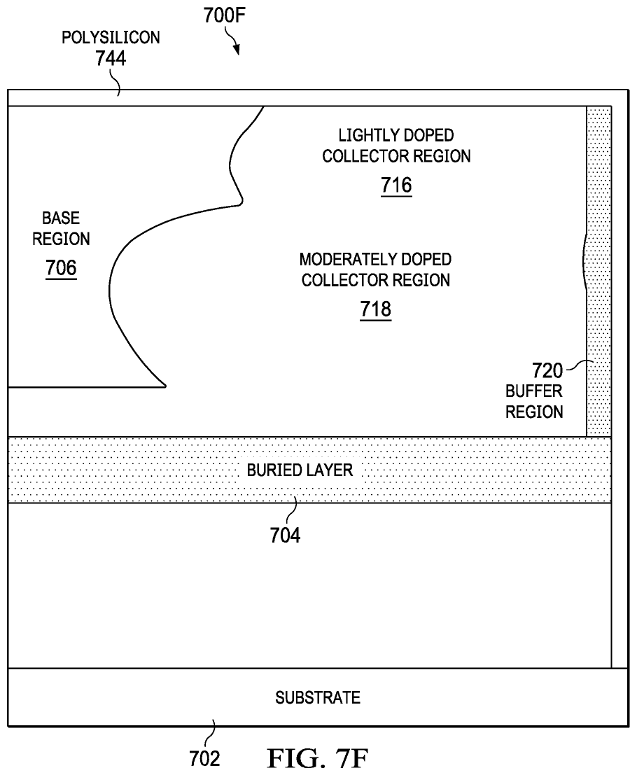

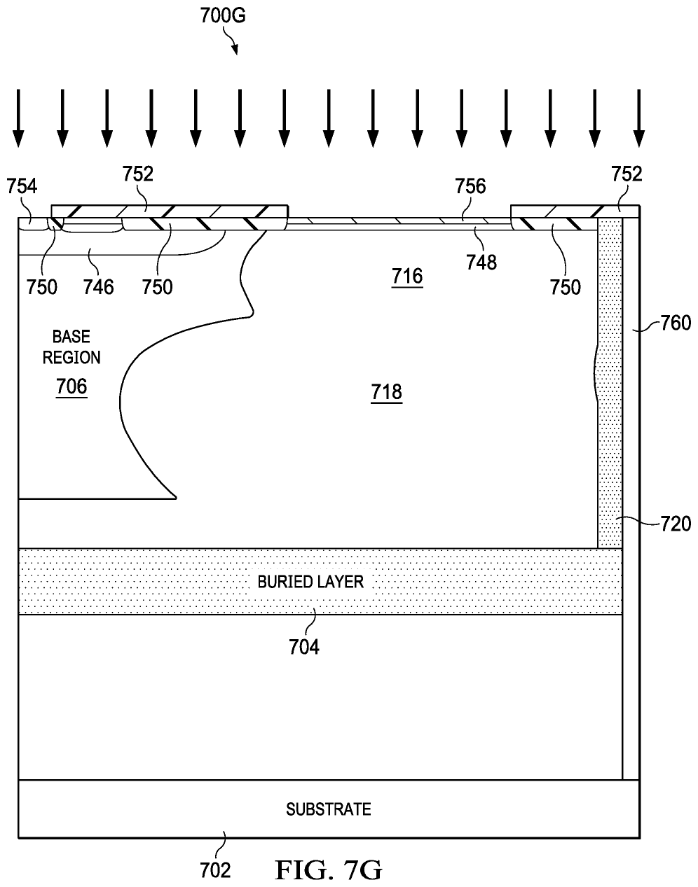

FIG. 6 depicts a method 600 of fabricating a vertical bipolar transistor according to an embodiment of the disclosure, while FIGS. 7A-7G depict a portion of a semiconductor substrate 700 containing the vertical BJT at various points during the fabrication. Where doping is referred to as simply lightly doped, moderately doped, etc., the following values are used for these ranges: lightly doped: 1 e15-9 e16 atoms/cm³, moderately doped: 9 e16-9 e17 atoms/cm³, heavily doped: 9 e17-9 e18 atoms/cm³and N++ from 1 e19-1 e20 atoms/cm³.

Method 600 begins with providing 605 a semiconductor substrate 700A (FIG. 7A) having a first P-type epitaxial layer 703 containing an N-type buried layer 704 and a second P-type epitaxial layer 705 overlying the first P-type epitaxial layer. In one embodiment, the substrate 702 of the semiconductor substrate is doped P+ and each of the first epitaxial layer 703 and second epitaxial layer 705 is doped P−. In one embodiment, each of the epitaxial layers is doped with about 1 e15 atoms/cm³ boron. In one embodiment, the first epitaxial layer 703 is about 17 μm thick and the second epitaxial layer 705 is about 7.3 μm thick.

Method 600 continues with implanting 610 a first N-type dopant in the second epitaxial layer 705 and annealing the semiconductor substrate thereby forming a moderately doped collector region, such as the moderately doped second collector region 118 of FIGS. 1A and 1B. In one embodiment, implanting and annealing the first N-type dopant includes the elements shown in method 600A of FIG. 6A, e.g., depositing and patterning 640 a photoresist layer 730 on semiconductor substrate 700B (FIG. 7B) to expose a desired moderately doped collector region. As seen in FIG. 7B, a first N-type dopant is implanted 645 using a high-energy implantation process to form an N-type region 732 as a buried layer within second epitaxial layer 705. Following the implantation, remaining photoresist is removed, e.g., by ashing and rinsing of the semiconductor substrate and the semiconductor substrate is annealed 650 to cause N-type region 732 to diffuse into the nearby region.

Returning to FIG. 6, method 600 continues with growing 615 a third epitaxial layer 707 on the second P-type epitaxial layer as shown in semiconductor substrate 700C (FIG. 7C). In one embodiment, this third epitaxial layer is a P− layer and is approximately 6.6 μm thick. A second N-type dopant is implanted 620 in the third epitaxial layer 707 and the semiconductor substrate is annealed, forming a lightly doped collector region, such as the lightly doped first collector region 116 (FIG. 1A) or the lightly doped first collector region 116′ (FIG. 1B). In one embodiment, implanting and annealing the second N-type dopant is performed as shown in method 600B and includes, as shown in FIG. 7C, depositing and patterning 660 a photoresist layer 734 on the semiconductor substrate 700C to expose a desired lightly doped collector region. The second dopant is implanted 665 into the semiconductor substrate to form N-type region 736 as a buried layer. The remaining photoresist is again removed and the semiconductor substrate is annealed 670, forming a lightly doped collector region 716 (FIG. 7D). It will be understood that although FIG. 7C depicts moderately doped collector region 718 as fully diffused during the implantation of N-type region 736 and defining the final junction with base region 706A, the dopants in moderately doped collector region 718 continue to diffuse each time an anneal process is performed until the process is completed, resulting in a final base region 706 (FIG. 7D).

To fabricate the embodiment of FIG. 1A, the same mask can be utilized to pattern photoresist layer 734 as was utilized to pattern photoresist layer 730. However, in the fabrication of the embodiment of FIG. 1B, the mask utilized to pattern photoresist layer 734 contains a smaller opening for the implant than the mask utilized to pattern photoresist layer 730. In one embodiment, the opening in photoresist layer 734 is sized such that in the finished transistor, a first lateral distance D1B between the N-type emitter 114 and the lightly doped collector region 116′ (FIG. 1B) is greater than a second lateral distance D2B between the N-type emitter and the moderately doped second collector region 118. In one embodiment, the ratio D1B:D2B is between about 2.1 and about 4.5, or in other words the first lateral distance is between about 210% and about 450% the second lateral distance.

Method 600 continues with implanting 625 a third N-type dopant thereby forming a moderately doped buffer region that extends from a surface of the semiconductor substrate to the moderately doped collector region and the N-type buffer region. In one embodiment, forming the moderately doped buffer region includes the elements of method 600C shown in FIG. 6C, and as seen in semiconductor substrate 700D of FIG. 7D, where a deep trench 738 is etched 680 to a first depth that contacts the lightly doped collector region 716, the moderately doped collector region 718 and the N-type buried layer 704. In one embodiment, the first depth is approximately 13 μm. In one embodiment, the deep trench 738 has a width of about 3.05 μm. Referring to FIG. 7E, as seen in semiconductor substrate 700E, method 600 next implants 685 the third N-type dopant through a sidewall of deep trench 738. In one embodiment, the third N-type dopant is phosphorus, which is doped to a concentration of about 2 e15 atoms/cm³ at implant energy of 200 KeV in four rotations. A tilt of 16 degrees and a twist of 45 degrees are utilized. The implantation forms N-type region 742, which diffuses during subsequent annealing to form moderately doped buffer region 720 (FIG. 7F).

In one embodiment, forming the moderately doped buffer region 720 includes the elements shown in FIG. 6D, and incremental stages of manufacturing not explicitly shown between FIGS. 7E and 7F. Following the implanting for the moderately doped buffer region in step 685, deep trench 738 is etched 690 to a second depth that contacts a P-type substrate region 702 below the buried layer 704. The second depth can be in the range of about 15 μm to about 30 μm. In one embodiment, the second depth is about 30 μm. Hardmask layer 740 can then be removed. A thin layer of oxide (not specifically shown) is grown 695 on the sidewalls of deep trench 738. FIG. 7F shows semiconductor substrate 700F after a layer of polysilicon 744 is deposited 697 on the semiconductor substrate 700F and within deep trench 738. In one embodiment, the oxide sidewalls are grown to a depth of about 250 nm and the polysilicon 744 is doped P+ to provide a connection to the substrate. Excess polysilicon can then be removed with chemical-mechanical polishing, leaving a deep trench contact 760 within the deep trench 738.

The method 600 of fabricating the transistors shown in FIGS. 1A and 1B continues from this point with implanting the various P-wells and N-wells shown in these figures, such as P-well 746 and N-well 748, as well as the formation of shallow trench isolation 750. As seen in semiconductor substrate 700G (FIG. 7G), these elements have been formed and a photoresist 752 has been deposited and patterned to expose a desired emitter region 754 in the base region 706 and also to expose a collector contact region 756 over the lightly doped collector region 716. A fourth N-type dopant is implanted 630, forming the emitter region 754 and collector contact region 756. Although not specifically illustrated in the figures, method 600 then moves to form a silicide on the contact regions and to provide inter-level dielectrics, vias and metallization layers.

Applicants have disclosed embodiments of a vertical bipolar transistor that can be utilized for ESD protection and which provides a path that guides the current deeper into the collector region and away from the surface path that can cause premature failure. The deeper path is encouraged by having a lightly doped collection region near the surface of the semiconductor substrate and a moderately doped collector region underlying the lightly doped collector region. The lightly doped collector region may be implanted through a smaller opening than is the moderately doped collector region and may have a lateral width in the range of 0.6 to 0.8 times the width of the moderately doped collector region. A moderately doped buffer region extends from the surface of the semiconductor substrate to a buried layer below the moderately doped collector region and is laterally offset from the base region of the transistor but in a path of conduction. The disclosed embodiments may provide one or more of decreased current crowding, increased current uniformity and decreased failure.

Although various embodiments have been shown and described in detail, the claims are not limited to any particular embodiment or example. None of the above Detailed Description should be read as implying that any particular component, element, step, act, or function is essential such that it must be included in the scope of the claims. Reference to an element in the singular is not intended to mean “one and only one” unless explicitly so stated, but rather “one or more.” All structural and functional equivalents to the elements of the above-described embodiments that are known to those of ordinary skill in the art are expressly incorporated herein by reference and are intended to be encompassed by the present claims. Accordingly, those skilled in the art will recognize that the exemplary embodiments described herein can be practiced with various modifications and alterations within the spirit and scope of the claims appended below.

1. An integrated circuit (IC) comprising:
a semiconductor substrate having a first conductivity type; and
a transistor formed within the semiconductor substrate the transistor comprising:
a buried layer located within the semiconductor substrate and having a second conductivity type;
a first doped region having the first conductivity type located between the buried layer and a surface of the substrate;
a second doped region having the second conductivity type extending from the substrate surface to the buried layer;
a third doped region, located between the buried layer and the surface and between the first doped region and the second doped region, the third doped region having the second conductivity type and a first dopant concentration; and
a fourth doped region located between the third doped region and the substrate surface and between the first doped region and the second doped region, the fourth doped region having the second conductivity type and a second dopant concentration less than the first dopant concentration.

2. The IC as recited in claim 1 further comprising a fifth doped region of the second conductivity type located within the first doped region such that the first doped region is located between the fifth doped region and the second doped region.

3. The IC as recited in claim 2 wherein a first lateral distance between the fifth doped region and the fourth doped region is greater than a second lateral distance between the fifth doped region and the third doped region.

4. The IC as recited in claim 3 wherein the ratio of the first lateral distance to the second lateral distance is between about 2.1 and about 4.5 inclusive.

5. The IC as recited in claim 1 wherein the buried layer is formed in a first epitaxial layer grown on the substrate, the third doped region is formed in a second epitaxial layer grown over the first epitaxial layer, and the fourth doped region is formed in a third epitaxial layer grown over the second epitaxial layer.

6. The IC as recited in claim 1 further comprising a sixth doped region having the first conductivity type extending from the surface to the buried layer, the second doped region located between the first doped region and the sixth doped region.

7. The IC as recited in claim 6 wherein the sixth doped region extends from the substrate surface to a substrate region having the first conductivity type.

8. The IC as recited in claim 1, wherein the first conductivity type is P-type and the second conductivity type is N-type.

9. The IC as recited in claim 1, further comprising functional circuitry formed on the surface of the semiconductor substrate, wherein a terminal of the transistor is connected to an node of the functional circuitry.

10. A transistor, comprising:
a base region at a surface of a semiconductor substrate, the base region being doped P-type;
an emitter that is N-type and is formed in the base region;
an N-type buffer region extending from the substrate surface into the substrate; and
an N-type collector comprising
a first collector region that has a first dopant concentration and that extends from the buffer region towards the base region a first distance;
a second collector region that has a second dopant concentration that is higher than the first dopant concentration, underlies the first collector region and extends from the buffer region towards the base region a second distance; and
a collector contact region at the surface of the substrate, the collector contact region being doped a third dopant concentration that is higher than the second dopant concentration, is connected to the buffer region, and is separated from the first collector region by a region having a fourth dopant concentration lower than both the first dopant concentration and the third dopant concentration.

11. The transistor as recited in claim 10 further comprising a heavily doped N-type buried layer that has a dopant concentration greater than the second dopant concentration, contacts the buffer region and underlies both the base region and the second collector region.

12. The transistor as recited in claim 10 wherein the second distance is greater than the first distance.

13. The transistor as recited in claim 12 wherein a first lateral distance from the emitter to the first collector region is between about 210% and about 450% a second lateral distance from the emitter to the second collector region.

14. The transistor as recited in claim 11 further comprising a deep trench that extends from the substrate surface to the substrate underlying the N-type buried layer.

15. The transistor as recited in claim 14, wherein the underlying substrate is P-type and the deep trench is filled with P-type polysilicon.

16. A method of fabricating an integrated circuit (IC), comprising:
providing a semiconductor substrate having an N-type buried layer located within first P-type epitaxial layer;
implanting a first N-type dopant into the second epitaxial layer and annealing the semiconductor substrate thereby forming a moderately doped collector region;
forming a second P-type epitaxial layer over the moderately doped collector region;
implanting a second N-type dopant in the third P-type epitaxial layer and annealing the semiconductor substrate thereby forming a lightly doped collector region overlying the moderately doped collector region; and
implanting a third N-type dopant into the lightly doped collector region and the moderately doped collector region and annealing the semiconductor substrate thereby forming a moderately doped buffer region that extends from a surface of the semiconductor substrate to the N-type buried layer.

17. The method as recited in claim 16 further forming an N++ collector contact region over the lightly doped collector region.

18. The method as recited in claim 17 wherein the lightly doped collector region extends a first lateral distance from the buffer region, and the moderately doped collector region extends a second greater lateral distance from the buffer region.

19. The method as recited in claim 16 wherein implanting the third N-type dopant comprises:
etching a deep trench to a first depth that contacts the moderately doped collector region and the N-type buried layer; and
implanting the third N-type dopant through a sidewall of the deep trench opening.

20. The method as recited in claim 19 further comprising:
after implanting the third N-type dopant, etching the deep trench to a second depth that contacts a P-type substrate region below the buried layer;
growing a thin layer of oxide on sidewalls of the deep trench; and
depositing P+ polysilicon within the deep trench.

21. The method as recited in claim 16 further comprising forming an N-type emitter region in a surface of the third epitaxial layer and a P-type base contact region between the emitter region and the lightly doped collector region.

22. The method as recited in claim 16 wherein a ratio of a first lateral distance, which is between the emitter region and the first collector region, to a second lateral distance, which is between the emitter region and the second collector region, is between about 2.1 and about 4.5.
